(19) United States
(12) Patent Application Publication
(10) Pub. No.: US 2022/0020665 A1
(43) Pub. Date: Jan. 20, 2022

(54) DOUBLE-SIDE BACK-END-OF-LINE METALLIZATION FOR PSEUDO THROUGH-SILICON VIA INTEGRATION

(71) Applicant: QUALCOMM Incorporated, San Diego, CA (US)

(72) Inventors: Xia Li, San Diego, CA (US); Bin Yang, San Diego, CA (US); Haining Yang, San Diego, CA (US)

(21) Appl. No.: 16/928,759

(22) Filed: Jul. 14, 2020

(51) Int. Cl. H01L 23/48; H01L 23/522; H01L 25/065; H01L 23/528; H01L 21/762

(52) U.S. Cl. CPC H01L 23/481; H01L 23/5226; H01L 2225/06513; H01L 23/5286; H01L 21/76254; H01L 25/0652

(57) ABSTRACT

Methods, systems, and devices for double side back-end-of-line (BEOL) metallization for pseudo through-silicon via (pTSV) integration are described. An integrated circuit (IC) may include multiple metallic layers integrated within multiple layers of a multi-dimensional integrated stack (e.g., a three dimensional (3D) integrated stack). By performing a BEOL metallization process, the integrated circuit may implement techniques for 3D vertical chip integration. For example, a first set of layers may be formed during a first portion of a BEOL process and a second portion of the BEOL process may integrate a second set of metallic layers as well as a buried power delivery network (PDN). The metallic layers may form a number of pTSVs and may promote a PDN to experience a reduced PDN IR drop. The PDN may be integrated and the pTSVs may be formed by integrating the metallic layers within a number of dielectric layers.

### BACKGROUND

The following relates generally to integrated circuits (IC) and more specifically to methods of integrating pseudo through-silicon vias (pTSVs) with buried power delivery networks (PDN) for reduced power delivery network voltage (PDN-IR) drop.

IC packages are widely deployed in various types of portable electronic devices, such as mobile phones, laptop computers, and the like. Due to increasing demand for smaller, lighter, and faster portable devices there is increased demand for circuit components having greater capacity, performance, and smaller dimensions. For example, such portable devices may include IC packages with a power delivery network (PDN) and a power management integrated circuit (PMIC). In some techniques such as “through-silicon stacking” (TSS), multiple vertically stacked semiconductor dies are electrically coupled to one another using through-silicon vias (TSVs). TSVs are electrical conductors typically made of metal that pass vertically through the thickness of a die's substrate such that one end is exposed at a back side surface of the die substrate, and another, opposite end is electrically coupled to the active surface of the die.

Various techniques for manufacturing ICs may be deployed to reduce a footprint of ICs and related technologies. ICs with critical dimension (CD) less than five nanometers (e.g., 5 nm beyond technologies) may suffer an undesirable PDN-IR drop, which may impact performance of some devices. Some ICs may be deployed with TSVs in a multidimensional integrated architecture to reduce a chip size and mitigate undesirable PDN-IR drop, but integrating TSVs may involve high manufacturing costs, may be incompatible with other desired manufacturing processes, such as a complementary-metal-oxide-semiconductor (CMOS) process, and may involve large keep out zones in order to avoid undesired stress impact on devices. As demand for reducing integrated device CDs for ICs increases, it may be desirable to provide improvements to manufacturing ICs with decreased or eliminated undesirable PDN-IR drops.

### SUMMARY

The described techniques relate to improved methods, systems, devices, and apparatuses that support double-side back-end-of-line (BEOL) metallization for pseudo through-silicon via (pTSV) integration. Various aspects of the described techniques relate to enabling a reduced integrated circuit (IC) critical dimension (CD) while mitigating undesirable power delivery network power (PDN-IR) drops, for example, in multi-dimensional integrated architectures. The described techniques may use a frontside and a backside BEOL metallization procedure to integrate a multidimensional IC chip integration with pTSVs for reduced PDN-IR drops. By performing a frontside and a backside BEOL metallization process, the IC may implement techniques for multi-dimensional (e.g., 3D) vertical chip integration that reduces PDN IR drop and may be compatible with other desired manufacturing processes (e.g., such as a complementary-metal-oxide-semiconductor (CMOS) process) while avoiding high manufacturing costs.

A backside BEOL metallization may enable a backside PDN and form first portions of a set of pTSVs which may aid in reducing IR drop, while a frontside BEOL metallization may form second portions of the set of pTSVs to enable vertical integration and avoid manufacturing costs associated with traditional TSVs while providing a CMOS process compatibility not available with traditional TSVs. The method of forming an IC, including a backside BEOL and a frontside BEOL metallization process, may include forming a plurality of pTSVs connecting a package substrate with one or more components of an electronic device. The PDN may be integrated and the pTSVs may be formed by integrating a plurality of metallic layers within a number of dielectric layers, where a first portion of the metallic layers may be deposited in a backside BEOL metallization process and a second portion of the metallic layers may be deposited in a frontside BEOL metallization process. Such an implementation may improve chip performance in semiconductor devices with reduced CD and chip size (e.g., 5 nm beyond semiconductor devices).

A device is described. The device may include a first metallic layer coupled to a first set of vias, a second metallic layer coupled to a second set of vias, a set of inter-metal dielectrics positioned between the first metallic layer and the second metallic layer, a first set of metal layers within a first subset of the set of inter-metal dielectrics, a second set of metal layers with a second subset of the set of inter-metal dielectrics, where the first subset and the second subset are different, and a power delivery network embedded at least partially within the first subset of the set of inter-metal dielectrics.

Some examples of the device described herein may further include a set of input and output contacts coupled to the second set of metal layers, where a portion of the set of input and output contacts may be coupled to the second set of vias with a set of chips.

Some examples of the device described herein may further include a memory chip coupled to a first via through an input and output contact of the set of input and output contacts, and a radio frequency chip coupled to a second via through a second input and output contact of the set of input and output contacts.

In some examples of the device described herein, the first set of metal layers and the second set of metal layers may be coupled via a set of metal layers embedded within a third subset of the set of inter-metal dielectrics.

In some examples of the device described herein, the power delivery network may be coupled to the first set of metal layers.

Some examples of the device described herein may further include a set of n-type transistors coupled to the first set of metal layers or the second set of metal layers, or both, and a set of p-type transistors coupled to the first set of metal layers or the second set of metal layers, or both, where the power delivery network may be coupled to the set of n-type transistors or the set of p-type transistors, or both, via the first set of metal layers.

Some examples of the device described herein may further include a first voltage supply coupled to the set of n-type transistors, and a second voltage supply coupled to the set of p-type transistors.

In some examples of the device described herein, vias of the first set of vias and the second set of vias may be pseudo through-silicon vias.

In some examples of the device described herein, the first set of metal layers may be formed based at last in part on a backside back end of a line metallization.

In some examples of the device described herein, the second set of metal layers may be formed based at last in part on a frontside back end of a line metallization.

A method of forming a semiconductor device is described. The method may include forming a first metallic layer coupled to a first set of vias, forming a second metallic layer coupled to a second set of vias, forming a set of inter-metal dielectrics positioned between the first metallic layer and the second metallic layer, forming a first set of metal layers within a first subset of the set of inter-metal dielectrics, forming a second set of metal layers with a second subset of the set of inter-metal dielectrics, where the first subset and the second subset are different, and forming a power delivery network embedded at least partially within the first subset of the set of inter-metal dielectrics.

An apparatus for forming a semiconductor device is described. The apparatus may include a processor, memory coupled with the processor, and instructions stored in the memory. The instructions may be executable by the processor to cause the apparatus to form a first metallic layer coupled to a first set of vias, form a second metallic layer coupled to a second set of vias, form a set of inter-metal dielectrics positioned between the first metallic layer and the second metallic layer, form a first set of metal layers within a first subset of the set of inter-metal dielectrics, form a second set of metal layers with a second subset of the set of inter-metal dielectrics, where the first subset and the second subset are different, and form a power delivery network embedded at least partially within the first subset of the set of inter-metal dielectrics.

Another apparatus for forming a semiconductor device is described. The apparatus may include means for forming a first metallic layer coupled to a first set of vias, forming a second metallic layer coupled to a second set of vias, forming a set of inter-metal dielectrics positioned between the first metallic layer and the second metallic layer, forming a first set of metal layers within a first subset of the set of inter-metal dielectrics, forming a second set of metal layers with a second subset of the set of inter-metal dielectrics, where the first subset and the second subset are different, and forming a power delivery network embedded at least partially within the first subset of the set of inter-metal dielectrics.

A non-transitory computer-readable medium storing code for forming a semiconductor device is described. The code may include instructions executable by a processor to form a first metallic layer coupled to a first set of vias, form a second metallic layer coupled to a second set of vias, form a set of inter-metal dielectrics positioned between the first metallic layer and the second metallic layer, form a first set of metal layers within a first subset of the set of inter-metal dielectrics, form a second set of metal layers with a second subset of the set of inter-metal dielectrics, where the first subset and the second subset are different, and form a power delivery network embedded at least partially within the first subset of the set of inter-metal dielectrics.

Some examples of the method, apparatuses, and non-transitory computer-readable medium described herein may further include operations, features, means, or instructions for depositing an oxide layer on an upper surface of a wafer associated with the semiconductor device, where the wafer includes a handle wafer or a glass wafer.

Some examples of the method, apparatuses, and non-transitory computer-readable medium described herein may further include operations, features, means, or instructions for depositing a graphene layer on an upper surface of the wafer, and depositing one or more silicon layers on an upper surface of the graphene layer, where depositing the oxide layer includes.

Some examples of the method, apparatuses, and non-transitory computer-readable medium described herein may further include operations, features, means, or instructions for forming one or more silicon-germanium layers between the one or more silicon layers by interleaving the one or more silicon-germanium layers between the one or more silicon layers.

Some examples of the method, apparatuses, and non-transitory computer-readable medium described herein may further include operations, features, means, or instructions for depositing a metal layer on an upper surface of the oxide layer, the metal layer including nickel.

Some examples of the method, apparatuses, and non-transitory computer-readable medium described herein may further include operations, features, means, or instructions for positioning a thermal handle mechanism on an upper surface of the metal layer, and performing a mechanical exfoliation of the graphene layer using the thermal handle mechanism.

Some examples of the method, apparatuses, and non-transitory computer-readable medium described herein may further include operations, features, means, or instructions for forming a silicon on insulator wafer based on the mechanical exfoliation from the graphene layer using the thermal handle mechanism, releasing the thermal handle mechanism based on forming the silicon on insulator wafer, and performing an etching operation on the deposited metal layer on the upper surface of the oxide layer, where the etching operation includes a wet etching operation.

In some examples of the method, apparatuses, and non-transitory computer-readable medium described herein, forming the semiconductor may include operations, features, means, or instructions for performing a front end of a line patterning process.

In some examples of the method, apparatuses, and non-transitory computer-readable medium described herein, forming the semiconductor may include operations, features, means, or instructions for performing a back end of a line patterning process based on performing the front end of a line patterning process.

A device is described. The device may include a first pseudo through-silicon via coupled to a set of dielectric layers, a second pseudo through-silicon via coupled to the set of dielectric layers, a first set of metal layers coupled to a set of input and output contacts, a second set of metal layers coupled to a power management IC, a set of transistors coupled to the first set of metal layers, and a set of voltage sources coupled to the second set of metal layers.

### BRIEF DESCRIPTION OF THE DRAWINGS

FIG. 1 illustrates an example of a device that supports double-side back-end-of-line (BEOL) metallization for pseudo through-silicon via (pTSV) integration in accordance with examples as disclosed herein.

FIG. 2 illustrates an example of a device and associated operations that support double-side BEOL metallization for pTSV integration in accordance with examples as disclosed herein.

FIG. 3 shows an example of a device and associated operations that support double-side BEOL metallization for pTSV integration in accordance with examples as disclosed herein.

FIG. 4 an example of a device that supports double-side BEOL metallization for pTSV integration in accordance with examples as disclosed herein.

FIG. 5 shows a flowchart illustrating a method or methods that support double-side BEOL metallization for pTSV integration in accordance with examples as disclosed herein.

FIG. 6 shows a flowchart illustrating a method or methods that support double-side BEOL metallization for pTSV integration in accordance with examples as disclosed herein.

### DETAILED DESCRIPTION

Power delivery network IR (PDN IR) drop caused by frontside back-end-of-line (BEOL) fabrication steps may be problematic for advance integrated circuit (IC) technologies (e.g., 5 nm beyond technologies). PDN IR drop may negate any benefits provided by such advance technologies and negatively affect performance of small-scale ICs. In some cases, through silicon vias (TSVs) may provide advantages for advance technologies with 3D integrations, however, integration of TSVs in 3D architectures may overly complicate the fabrication process, may increase fabrication costs and such implementations may not be compatible with some fabrication processes such as a complementary-metal-oxide-semiconductor (CMOS) process. As demand for smaller, lighter, and faster portable devices increases, shrinking the critical dimension (CD) scale of such technologies may be desirable while maintaining or improving performance, however current processes may induce or increase PDN IR drop as IC dimensions scale. Processes for manufacturing advance ICs with TSVs may be inefficient and current processes may be incompatible with vertically stacked ICs, such 3D stacked integration architectures.

A backside BEOL metallization process may enable integration of a buried backside PDN with a PMIC which may reduce IR drop and may avoid implementing surface mounted components with a pitch of 25 μm or less (e.g., such as fine pitch surface mounted components) which may incur high costs. Additionally, implementing a frontside, as well as a backside BEOL (e.g., double-side BEOL) metallization process may integrate pseudo TSVs (pTSVs) which may, in turn enable 3D vertical chip integration. Double-side BEOL metallization may be compatible with some fabrication processes (e.g., CMOS process) and may thus provide advantages associated with TSVs while enabling 3D vertical chip integration and avoiding complications and costs associated with traditional TSVs. PTSVs as well as a buried PDN may be integrated through a double-side BEOL metallization process by depositing metal layers throughout the layers of an IC wafer during the BEOL processes. Fabrication of the 3D IC in such a manner may improve performance while minimizing chip footprint as well as package size.

An IC may be integrated with a multigate device such as a planar device, a fin field-effect transistor (FET) (FinFET) device, or a gate-all-around FET (GAAFET) device. The type of device used may depend on the formation process of an epitaxial transfer layer. For example, the type of multigate device may depend upon which of various growth techniques may be used to form materials or components of the epitaxy thin film transfer layer used to transfer portions of the IC from a donor wafer to a handle wafer (e.g., glass wafer). In some cases, such multigate devices may include an insulator layer such as a buried oxide (BOX) layer which may be deposited (e.g., formed, grown) on a handle wafer (e.g., a glass wafer). However, the method of formation for planar or FinFET devices may differ from the method of formation of GAAFET devices.

The method of forming a planar or FinFET device may include forming an epitaxy layer on a donor wafer different than the handle wafer. The epitaxy layer may, for example, include graphene, graphene compositions, or the like. Additional epitaxy layers may be deposited. For example, one or more silicon epitaxy layers may be deposited (e.g., formed, grown) upon the graphene layer and may be formed via heteroepitaxial growth (e.g., van der Waals epitaxy). In some cases, a protection layer may be deposited (e.g., formed, grown) to protect the device during subsequent handling, packaging, or both. The protection layer may be composed of an oxide, or an oxide composition, among other examples. In some cases, a stressor layer may be deposited and may introduce a crack near the edge of the substrate, and mechanically guide the crack as a single fracture front across the surface. The stressor layer may, for example include nickel or nickel compositions, among other examples, and may be referred to as a handling substrate.

Thermal handle tape may be applied to the stressor layer. The thermal handling tape may be used to assist in a mechanical removal (e.g., exfoliation) of one or more deposited layers from the epitaxial transfer layer and the donor wafer. For example, one or more of the handling substrate, the protection layer, and the one or more silicon epitaxy layers may be removed or exfoliated from the graphene epitaxy layer and the donor wafer. In such cases, the one or more layers exfoliated with the thermal handle tape may be deposited on an insulating layer which may, for example, be a first backside inter-metal dielectric (IMD) (e.g., IMDb1). The insulating layer may be located, deposited, or formed on a handle wafer or a glass wafer. In some cases, a surface of the protection layer (e.g., an oxide protection layer) may bond or be bonded with the one or more silicon epitaxy layers to form a Silicon-on-Insulator (SOI) wafer.

A thermal de-taping process may be implemented to remove or release the handle tape. For example, a temperature of about 90° Celsius may be applied in the de-taping process, among other examples. In some cases, the handling substrate may also be removed. For example, a FeCl3 solution may be applied to the handling substrate to etch remove the layer, which may, for example, be composed of Ni metal. In some example cases, for example, cases in which the handling substrate is removed, the exposed oxide layer may be etched in a wet etch process, or cleaned, or both. The etched and/or cleaned wafer including one or more of the oxide layer, the silicon epitaxy layer and the handle wafer may be annealed such that binding between the silicon and oxide layers may be enhanced which may form a shallow trench isolation (STI) wafer with a tunable Si layer thickness and a tunable box layer.

The method of forming a GAAFET device may also include forming an epitaxy transfer layer on a donor wafer. The epitaxy transfer layer may, for example, include graphene, graphene compositions, or the like. Additional epitaxy layers may be deposited. For example, one or more SiGe or Si epitaxy layers, or both may be deposited (e.g., formed, grown) upon the graphene layer and may be formed via heteroepitaxial growth (e.g., van der Waals epitaxy). In some cases, layers of SiGe may alternate with layers of Si and, in some cases, the first deposited epitaxy layer and the last deposited epitaxy layer may be composed of SiGe. In some cases, a protection layer may be deposited (e.g., formed, grown) to provide the device during subsequent handling, or packaging, or both. The protection layer may be composed of an oxide or an oxide composition, among other examples. In some cases, a stressor layer may be deposited and may introduce a crack near the edge of the substrate, and mechanically guide the crack as a single fracture front across the surface. The stressor layer may, for example include nickel or nickel compositions, among other examples and may be referred to as a handling substrate.

Thermal handle tape may be applied to the stressor layer. The thermal handling tape may be used to assist in a mechanical removal (e.g., exfoliation) of one or more deposited layers. For example, one or more of the handling substrate, the protection layer, and the one or more Si and/or SiGe epitaxy layers may be removed or exfoliated from the graphene epitaxy layer and the donor wafer. In such cases, the one or more layers exfoliated with the thermal handle tape may be deposited on a box layer which may, for example, be located, deposited, or formed on a handle wafer or a glass wafer. In some cases, the one or more silicon epitaxy layers may bond or be bonded with the bottom of the protection layer (e.g., an oxide protective layer). A thermal de-taping process may be implemented to remove or release the handle tape. For example, a temperature of about 90° Celsius may be applied in the de-taping process, among other examples. In some cases, the handling substrate may also be removed. For example, a FeCl3 solution may be applied to the handling substrate to etch remove the layer, which may, for example, be composed of Ni metal. In cases where the handling substrate is removed, the exposed oxide layer may be etched, or cleaned, or both. The one or more Si and/or SiGe layers may bond to the box layer and a SiN hard mask layer may be deposited upon the exposed (e.g., etched and cleaned) oxide layer.

An IC may be formed on any of a planar, FinFET GAAFET multigate device, or the like. In some cases, the multigate device may include an N-channel metal-oxide-semiconductor FET (MOSFET) (NMOS) and a P-channel MOSFET (PMOS) which may be deposited (e.g., formed, integrated, or the like) on the SOI wafer of the device (e.g., a planar device, FinFET device, GAAFET device, or the like). The PMOS and the NMOS may be portions of a PDN of the IC. The exposed silicon layer of the device may be patterned to form shallow trench isolation which may separate the NMOS and PMOS and may prepare the device for a front-end-of-line (FEOL) process. In some examples, the FEOL process may be a FEOL device patterning process and may include implementing one or more of well implantation, gate oxide growth, gate or dummy gate deposition and patterning, one or more form spacers, dummy gate replacement with a high-k metal gate for the NMOS and PMOS, epitaxy source/drain formation for the NMOS and PMOS, and the like. In some cases, an inter-layer dielectric (ILD) may be deposited and may be planarized through chemical-mechanical planarization (CMP).

In some examples, a middle-of-line (MOL) process may follow the FEOL process. The MOL process may include processing steps used to create structures that may provide electrical connections between the NMOS and PMOS transistors (e.g., gate contact formation). For example, the MOL process may include integrating one or more metallic layers within the ILD layer that form connections for the PMOS and the NMOS. Such layers may couple the NMOS and PMOS and may also provide contacts for coupling the NMOS, the PMOS, or both to other components of the IC. A BEOL process may follow a MOL process and may include steps that form interconnect structures. For example, one or more IMD layers as well as a top IMD may be deposited on the ILD layer. The IMD layers may include one or more sets of metallic layers. In some cases, the one or more sets of metallic layers may couple the transistors with other components via the IMD layers. In some cases, the metallic layers are integrated and stacked within the IMD layers as part of a frontside BEOL metallization process and may form first portions of one or more pTSVs and may form interconnect structures coupled to the PMOS and NMOS transistors. Additionally, a redistribution layer may be deposited on the top IMD layer and may be processed via passivation and patterning such that several wells are formed for integrating a first set of I/O bumps (e.g., including pTSV I/O bumps and PMOS and NMOS I/O bumps) in the passivation layer (e.g., redistribution layer) such that the bumps may be in contact with the top IMD layer.

The handle wafer and the deposited layers, including the layers deposited in the FEOL, MOL, and frontside BEOL processes as well as the integrated interconnect structures, may be flipped and bonded to a second handle wafer (e.g., glass wafer) and the first handle wafer may be removed to prepare the wafer for a backside BEOL process. In some examples, the passivation layer may be bonded to another epitaxial layer (e.g., composed of graphene, graphene compounds, and the like). The first handle wafer may be removed by grade lapping with the box layer. One or more sets of backside BEOL metallic layers may be integrated in the box layer, the STI layer, and the ILD layer such that the individual layers are coupled to one another. Each set of the one or more sets of backside BEOL metallic layers may form portions of the interconnect structures and may be coupled to one of the first portions of the one or more pTSVs or one of the NMOS or PMOS contacts through the first IMD layer deposited in the frontside BEOL process. The exposed side of the box layer may be planarized through CMP.

As part of the backside BEOL process, one or more sets of backside BEOL metallic layers may be integrated and may include positive voltage (VDD) and ground voltage (VSS) contacts formed in the box layer of the wafer which may serve as a buried PDN. In some cases, a backside IMD layer is deposited on the exposed side of the box layer and one or more set of metallic layers are integrated such that each set of the backside BEOL metallic layers may form a second portion of the one or more pTSVs or an interconnect structure for the PMOS and NMOS and may form interconnect structures for a buried PDN. The first pTSV portions and the second pTSV portions may be coupled and may form one or more pTSVs. Additionally, a second redistribution layer may be deposited on the backside IMD layer and may be processed via passivation and patterning such that several wells are formed for integrating bumps of one or more sizes. A first set of one or more bumps may be deposited in one or more wells of the second passivation layer and may be coupled to a PMIC such that the PMIC is coupled with the buried PDN as well as the PMOS and the NMOS transistors via the first set of bumps and the backside portions of the PMOS and NMOS metallic layer sets. Coupling the PMIC to the first set of bumps for the backside PDN may reduce PDN IR drop. A second set of one or more bumps of a different size than the first set of one or more bumps may be pTSV I/Os and may be deposited in remaining wells of the one or more of the wells of the second passivation layer and may be coupled to the frontside portions of the pTSVs via the backside portions of the pTSVs. In some cases, a height of the pTSV I/O bumps may be greater than the height of the PMIC in combination with the first set of bumps such that when a package lead frame substrate is attached to the pTSV I/Os, the PMIC and the substrate are separate from each other. In some cases, the pTSV I/O bumps may be composed of copper.

The handle wafer and the deposited layers, now including the layers deposited in the FEOL, MOL, frontside BEOL, backside BEOL processes and the package lead frame substrate, again may be flipped and the first handle wafer (e.g., glass wafer) may be removed in a laser de-bonding process. A third set of bumps including one or more pTSV I/O bumps as well as one or more PDN I/O bumps may be deposited in the one or more wells of the first passivation layer and may couple a memory chip and a radio frequency (RF) chip to the pTSVs as well as the buried PDN.

Aspects of the disclosure are initially described in the context of a semiconductor device. Aspects of the disclosure are further illustrated by and described with reference to apparatus diagrams, system diagrams, and flowcharts that relate to double-side BEOL metallization for pTSV integration.

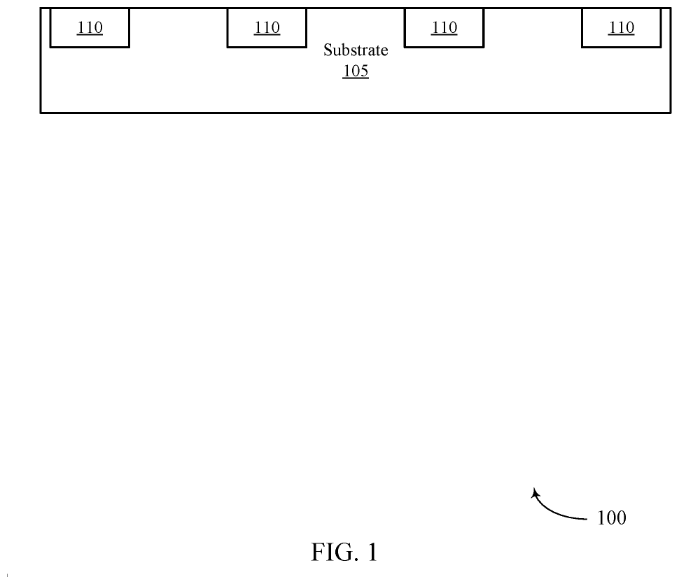

FIG. 1 illustrates a device 100 that supports double-side BEOL metallization for pTSV integration in accordance with aspects of the present disclosure. The device 100 may include a substrate 105, which may be silicon (Si), but may also be made of germanium (Ge), silicon germanium (SiGe), gallium arsenide (GaAs), gallium arsenide-phosphide (GaAsP), indium phosphide (InP), gallium aluminum arsenic (GaAlAS), indium gallium phosphide (InGaP), and the like. The device 100 may refer to a semiconductor wafer or an IC die on a semiconductor wafer. In some examples, the substrate 105 may be a bulk monolithic silicon substrate. In some examples, the substrate 105 may have a silicon-on-insulator (SOI) configuration. The device 100 may also include components 110 in substrate 105. In some examples, the components 110 may include one or more active or passive devices of an IC. Examples of the components 110 include metal-oxide-semiconductor field-effect transistors (MOSFET), bipolar junction transistors (BJT), diodes, resistors, capacitors, etc. Moreover, the components 110 in FIG. 1 may also represent a cluster of active and/or passive devices, a memory, and a functional circuitry with many active and/or passive devices, etc.

Various process flows may be utilized to form the components 110 in the substrate 105. For example, a film growth process, such as epitaxi growth process on the substrate 105, an oxidation process, such as oxidation semiconductor to form oxidation layers, a film deposition processes, such as chemical vapor deposition (CVD), spin-on, sputtering, and electroplating can be used to form conductive and dielectric layers on the substrate 105. Doping processes, such as diffusion and implantation can be used to add impurities in a semiconductor material to achieve desired conductivity, for example. Photolithography can be used to transfer patterns on a mask to a layer of material on the substrate 105, for example. Etching process can be performed after lithography to remove unwanted material layers, for example. Planarization process such as “etch-back and chemical-mechanical planarization (CMP) can be employed to create a flat surface for the next processing step, for instance. CMOS FEOL processing flows combining these and other processing steps may be implemented to form the components 110 for use in different applications, although other suitable processing techniques, such as bipolar and BiCMOS (bipolar and CMOS technology) may be implemented.

An IC may be integrated with the device 100 and the components 110 may for example be components of a planar device, a FinFET device, or a GAAFET device. The type of components 110 may depend upon various techniques used to form materials or elements of the device 100. The device 100 may be a multigate device and may be any of a planar, FinFET GAAFET multigate device, or the like. In some cases, the components 110 may include an NMOS and a PMOS which may be deposited (e.g., formed, integrated, or the like) on the bulk of the SOI wafer of the device 100 (e.g., a planar device, FinFET device, GAAFET device, or the like). The PMOS and the NMOS may be portions of a PDN of the IC. The exposed silicon layer of the device may be patterned to form shallow trench isolation which may separate the NMOS and PMOS and may prepare the device for a front-end-of-line (FEOL) process. In some examples, the FEOL process may be a FEOL device patterning process and as described herein may include implementing one or more processes for forming transistors and other circuit elements (such as resistors and capacitors, etc.) that may be later coupled electrically with other component of the IC.

The device 100 may provide a foundation for forming an IC with pTSVs and buried PDN through frontside and backside BEOL processes. The techniques described herein may provide improvements in device performance. Further, the techniques described herein may provide benefits and enhancements to the operation of the device 100. For example, by forming an IC on the device 100 by implementing a double-side BEOL process, an IC may be formed that provides advantages over other devices, such as reduced PDN IR drop. The techniques described herein may also enable circuit components with greater performance and smaller dimensions by implementing processes related to double-side BEOL metallization for pTSV integration. One or more of the process described herein may be included in one or more of a FEOL, MOL, or frontside BEOL process. Additionally or alternatively, the FEOL, MOL and the frontside BEOL may have more or fewer processing steps than the examples described herein.

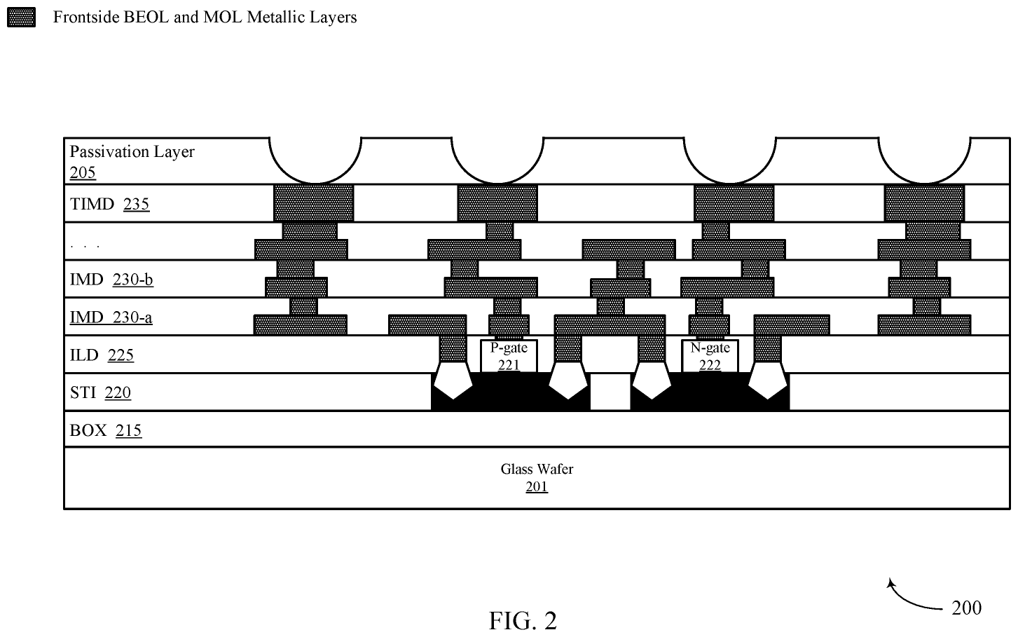

FIG. 2 illustrates a device 200 that supports double-side BEOL metallization for pTSV integration in accordance with aspects of the present disclosure. In some examples, FIG. 2 illustrates a portion of an IC of the device 200 formed through a frontside BEOL metallization process which may also be referred to as a wiring process. The device 200 may be an example of or include portions or components such as those described in FIG. 1. It should be understood that the example as described with reference to FIG. 2 is an example implementation and the frontside BEOL metallization process may more or fewer processing steps than the example described herein.

The frontside BEOL metallization process may be performed after an FEOL process in which transistors such as a P-gate 221 (e.g., PMOS) and an N-gate 222 and other elements are formed and after an MOL process in which structures that may provide local electrical connections between transistors (e.g., the P-gate 221 and the N-gate 222) are formed. The device 200 may include multiple stacked layers of various materials. For example, the device 200 may include a handle wafer or a glass wafer 201 and may provide a base upon which other layers are formed. In some cases, the device 200 may include a multigate device such as a planar device, an FinFET, or a GAAFET device. The type of device used may depend on the formation process of an epitaxial transfer layer. For example, the type of multigate device may depend upon which of various growth techniques may be used and patterning methods may be used to form materials or components of the epitaxy thin film transfer layer used to transfer portions of the IC from a donor wafer to a handle wafer (e.g., glass wafer). In the example of FIG. 2, a planar multigate device is shown and may include the glass wafer 201, a box layer 215 and a silicon layer which may be formed into an STI layer 220. In some cases, the box layer 215 which may be deposited (e.g., formed, grown) on the glass wafer 201. The method of formation for planar or FinFET devices may differ from the method of formation of GAAFET devices.

The method of forming a planar or FinFET device may include forming an epitaxy layer on a donor wafer different than the handle wafer. The epitaxy layer may, for example, include graphene, graphene compositions, or the like. Additional epitaxy layers may be deposited. For example, one or more silicon epitaxy layers may be deposited (e.g., formed, grown) upon the graphene layer and may be formed via heteroepitaxial growth (e.g., van der Waals epitaxy). In some cases, a protection layer may be deposited (e.g., formed, grown) to protect the device during subsequent handling, packaging, or both. The protection layer may be composed of an oxide, or an oxide composition, among other examples. In some cases, a stressor layer may be deposited and may introduce a crack near the edge of the substrate, and mechanically guide the crack as a single fracture front across the surface. The stressor layer may, for example include nickel or nickel compositions, among other examples, and may be referred to as a handling substrate.

A thermal handle tape may be applied to the stressor layer. The thermal handling tape may be used to assist in a mechanical removal (e.g., exfoliation) of one or more deposited layers from the epitaxial transfer layer and the donor wafer. For example, one or more of the handling substrate, the protection layer, and the one or more silicon epitaxy layers may be removed or exfoliated from the graphene epitaxy layer and the donor wafer. In such cases, the one or more layers exfoliated with the thermal handle tape may be deposited on an insulating layer which may, for example, be a first inter-metal dielectric layer. The insulating layer may be located, deposited, or formed on a handle wafer or a glass wafer. In some cases, a surface of the protection layer (e.g., an oxide protection layer) may bond or be bonded with the one or more silicon epitaxy layers to form a Silicon on Insulator (SOI) wafer, which may include the first IMD and the glass wafer 201.

A thermal de-taping process may be implemented to remove or release the handle tape. For example, a temperature of about 90° Celsius may be applied in the de-taping process, among other examples. In some cases, the handling substrate may also be removed. For example, a FeCl3 solution may be applied to the handling substrate to etch remove the layer, which may, for example, be composed of Ni metal. In some example cases, for example, cases in which the handling substrate is removed, the exposed oxide layer may be etched in a wet etch process, or cleaned, or both. The etched and cleaned device 200 including one or more of the oxide layer, the silicon epitaxy layer and the handle wafer may be annealed such that binding between the silicon and oxide layers may be enhanced which may form an STI layer 220 of the device 200 with a tunable Si layer thickness and a tunable box layer 215 on the glass wafer 201. The STI layer may be patterned such that the N-gate 222 and the P-gate 221 are separated on the SOI layer.

An FEOL process may include a number of steps as described with reference to FIG. 1 and may prepare the device 200 for an MOL process. An ILD layer 225 may be deposited on an exposed surface on the STI layer 220 and may be planarized by a CMP process. The MOL process may include processing steps used to create structures that may provide electrical connections between the N-gate 222 and the P-gate 221 (e.g., NMOS and PMOS transistors). For example, the MOL process may include a gate contact formation. For example, the MOL process may include integrating one or more metallic layers within the ILD layer 225 that form connections for the N-gate 222 and the P-gate 221. Such layers may couple the NMOS and PMOS and may also provide contacts for coupling the N-gate 222 and the P-gate 221, or both to other components of the device 200.

A frontside BEOL process may follow the MOL process and may include steps that form interconnect structures. For example, one or more IMD layers 230 as well as a top IMD (TIMD) layer 235 may be deposited on the IMD layers 230. The IMD layers 230 as well as the TIMD 235 may include one or more sets of metallic layers. In some cases, the one or more sets of metallic layers may couple the N-gate 222 and the P-gate 221 with other components via the IMD layers. In some cases, the metallic layers are integrated and stacked within the IMD layers 230 and TIMD 235 as part of a frontside BEOL metallization process and may form first portions of one or more pTSVs and may form interconnect structures coupled to the N-gate 222 and the P-gate 221. Additionally, a layer may be deposited on the TIMD layer 235 and may be processed via passivation and patterning such that the passivation layer 205 includes several wells formed for integrating I/O bumps in the passivation layer 205 (e.g., redistribution layer) such that the bumps may be in contact with the TIMD layer 235.

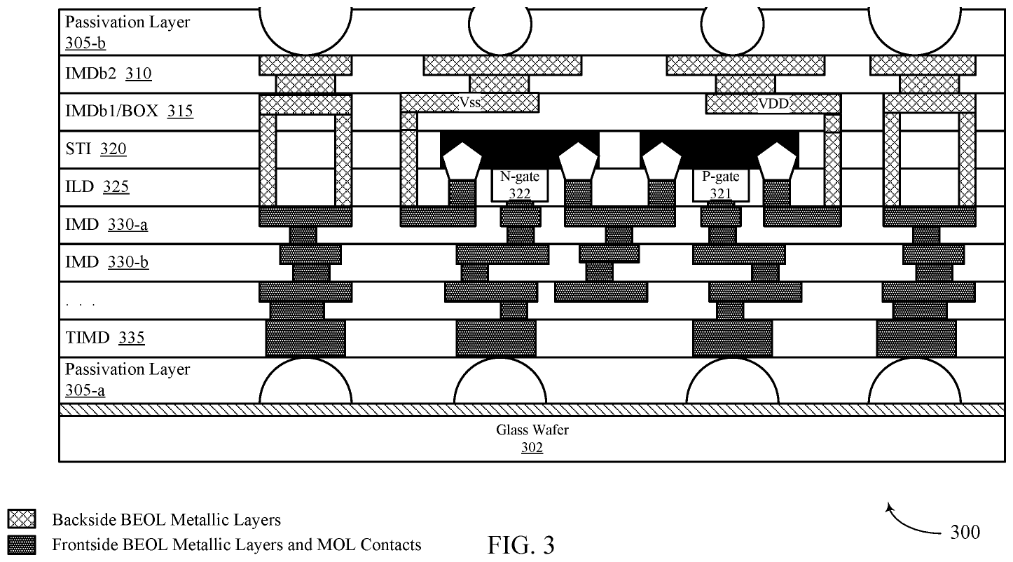

FIG. 3 illustrates a device 300 that supports double-side BEOL metallization for pTSV integration in accordance with aspects of the present disclosure. In some examples, FIG. 3 illustrates a portion of an IC of the device 300 formed through a frontside BEOL metallization as described with reference to FIG. 2 and a backside BEOL metallization process as described herein. The device 300 may be configured in accordance with an FEOL, MOL, or double-side BEOL process. The device 300 may be an example of or include portions or components such as those described in FIGS. 1 and 2. It should be understood that the example as described with reference to FIG. 3 is an example implementation and the backside BEOL metallization process may more or fewer processing steps than the example described herein.

The device 300 may include one or more frontside BEOL metallic wafers, as well as one or more MOL contacts. For example, the device 300 may include a glass wafer 302, a passivation layer 305-a which may be an example of passivation layer 205 as described with reference to FIG. 2. The device 300 may also include a TIMD 335, IMD layers 330, an ILD layer 325, a box layer 315, an N-gate 322, and a P-gate 321 which may be examples of the corresponding components as described with reference to FIG. 2. A first glass wafer (e.g., a glass wafer 201 as described with reference to FIG. 2) and the layers deposited in the FEOL, MOL, and frontside BEOL processes, may be flipped and bonded to a second glass wafer 302 and the first glass wafer (e.g., a glass wafer 201 as described with reference to FIG. 2) may be removed to prepare the wafer for a backside BEOL process. In some examples, the passivation layer 305-a may be bonded to another epitaxial layer (e.g., composed of graphene, graphene compounds, and the like). The first glass wafer (e.g., the glass wafer 201 as described with reference to FIG. 2) may be removed by grade lapping with the box layer 315.

One or more sets of backside BEOL metallic layers may be integrated in the box layer 315 (which may also be referred to as the first backside IMD (IMDb1) layer), the STI layer 320, and the ILD layer 325 such that the individual layers are coupled to one another vias one or more sets of backside BEOL metallic layers. Each set of the one or more sets of backside BEOL metallic layers may form portions of interconnect structures and may be coupled to one of the first portions of the one or more pTSVs or one of the contacts of the N-gate 322, and the P-gate 321 through a first IMD layer 330-a deposited in the frontside BEOL process as described with reference to FIG. 2. The exposed side of the box layer 315 may be planarized through CMP.

As part of the backside BEOL process, one or more sets of backside BEOL metallic layers may be integrated and may include positive voltage (VDD) and ground voltage (VSS) contacts formed in the box layer 315 of the device 300 which may serve as voltage contacts for a buried PDN. In some cases, a second backside IMD (IMDb2) layer 310 may be deposited on the exposed side of the box layer 315 and one or more set of metallic layers may be integrated such that each set of the backside BEOL metallic layers may form a second portion of the one or more pTSVs or an interconnect structure for the N-gate 322, and P-gate 321 and may form interconnect structures for the buried PDN. The first pTSV portions (e.g., frontside BEOL metallic layers) and the second pTSV portions (e.g., frontside BEOL metallic layers) may be coupled and may form one or more pTSVs. Additionally, a second passivation layer 305-b (e.g., redistribution layer) may be deposited on the IMDb2 layer 310 and may be processed via passivation and patterning such that several wells are formed for integrating bumps of one or more sizes.

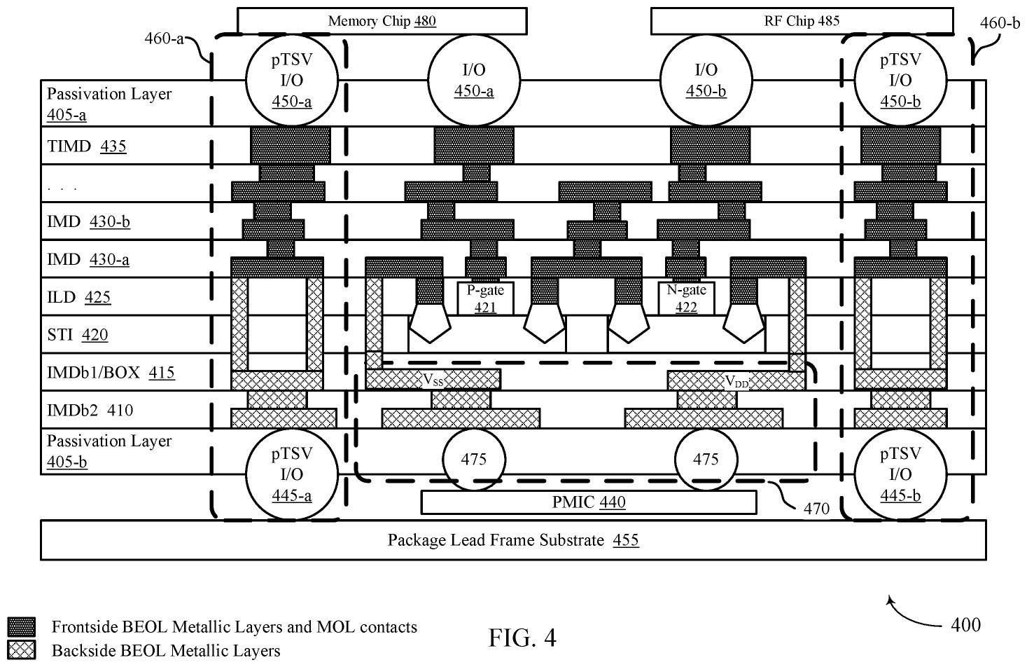

FIG. 4 illustrates a device 400 that supports double-side BEOL metallization for pTSV integration in accordance with aspects of the present disclosure. In some examples, FIG. 4 illustrates a portion of an IC of the device 400 formed through a frontside BEOL metallization as described with reference to FIG. 2 and a backside BEOL metallization process as described with reference to FIG. 3. The device 400 may be configured in accordance with an FEOL, MOL, or double-side BEOL process. The device 400 may be an example of or include portions or components such as those described in FIGS. 1 through 3. It should be understood that the example as described with reference to FIG. 4 is an example implementation and one or more of the FEOL, the MOL, or the double-side BEOL process may more or fewer processing steps than the example described herein.

The device 400 may include a passivation layers 405, an IMDb2 layer 410, an IMDb1 layer (e.g., a box layer) 415, an STI layer 420, an ILD layer 425, an IMD layers 430, an TIMD layer 435, an N-gate 422, and a P-gate 421 which may be examples of the corresponding layers described with reference to FIGS. 2 and 3. The device 400 may include a first set of one or more bumps 475 deposited in one or more wells of the second passivation layer 405-b and may be coupled to a PMIC 440, such that the PMIC 440 is coupled with a buried PDN 470 which may include the N-gate 422, the P-gate 421, and the V_{SS} and V_{DD} contacts, via the first set of bumps 475 and the MOL contacts.

Coupling the PMIC 440 to the first set of bumps 475 for the buried PDN 470 may, in some examples, reduce a PDN IR drop. A second set of one or more bumps 445, including pTSV I/O bumps 445-a and 445-b may be of a different size than the first set of one or more bumps 475 and may be deposited in remaining wells of the second passivation layer 405-b. The pTSV I/Os may be coupled to the frontside portions of the pTSVs 460 via the backside portions of the pTSVs 460. In some examples, a height of the pTSV I/O bumps 445 may be greater than the height of the PMIC 440 in combination with the first set of bumps 475 such that when a package lead frame substrate 455 is attached to the pTSV I/O bumps 445, the PMIC 440 and the substrate 455 are separate from each other. In some cases, the pTSV I/O bumps 445 may be composed of copper.

A glass wafer (e.g., a second glass wafer 302 as described with reference to FIG. 4) and the deposited layers, now including the layers deposited in the FEOL, MOL, frontside BEOL, backside BEOL processes and the package lead frame substrate, again may be flipped and the glass wafer (e.g., second glass wafer 302 as described with reference to FIG. 4) may be removed in a laser de-bonding process. A third set of bumps 450 including one or more pTSV I/O bumps 450-a and 450-d as well as one or more PDN I/O bumps 450-b and 450-c may be deposited in the one or more wells of the first passivation layer 405-a and may couple a memory chip 480 and an RF chip 485 to the pTSVs 460 as well as the buried PDN 470

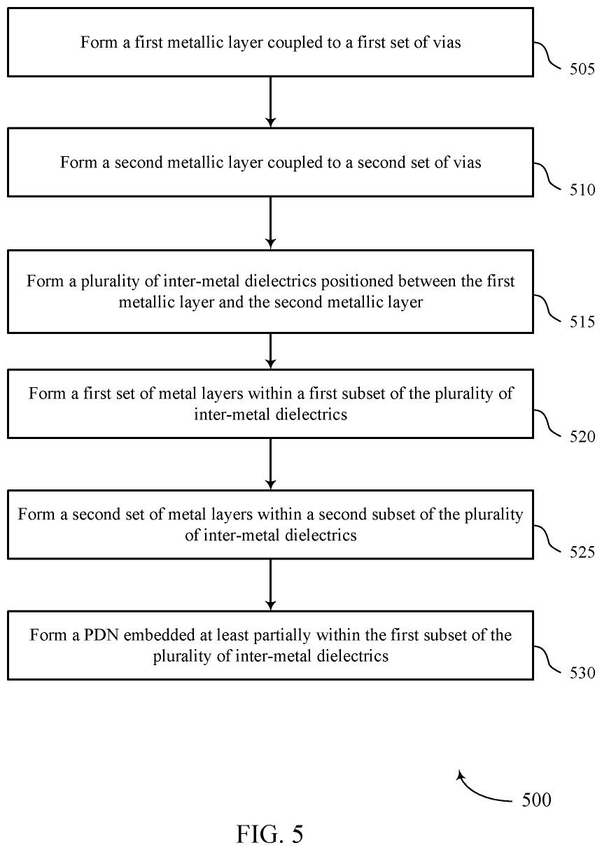

FIG. 5 shows a flowchart illustrating a method 500 of forming a semiconductor device in accordance with examples of the present disclosure. The operations of method 500 may be implemented by various fabrication techniques as described herein. For example, the operations of method 500 may be implemented by the fabrication techniques as discussed with reference to FIGS. 2 through 4.

At 505, a first metallic layer may be formed. In some examples, the first metallic layer may be coupled to a first set of vias. The operations of 505 may be performed according to the methods and fabrication techniques described herein. In some examples, aspects of the operations of 505 may be performed using the fabrication techniques discussed with reference to FIGS. 2 through 4.

At 510, a second metallic layer may be formed. In some examples, the first metallic layer may be coupled to a second set of vias. The operations of 510 may be performed according to the methods and fabrication techniques described herein. In some examples, aspects of the operations of 510 may be performed using the fabrication techniques discussed with reference to FIGS. 2 through 4.

At 515, a plurality of inter-metal dielectrics may be formed and may be positioned between the first metallic layer and the second metallic layer. The operations of 515 may be performed according to the methods and fabrication techniques described herein. In some examples, aspects of the operations of 515 may be performed using the fabrication techniques discussed with reference to FIGS. 2 through 4.

At 520, a first set of metal layers may be formed. In some examples, the first set of metal layer may be formed within a first subset of the plurality of inter-metal dielectrics. The operations of 520 may be performed according to the methods and fabrication techniques described herein. In some examples, aspects of the operations of 520 may be performed using the fabrication techniques discussed with reference to FIGS. 2 through 4.

At 525, a second set of metal layers may be formed. In some examples, the second set of metal layer may be formed within a second subset of the plurality of inter-metal dielectrics different from the first subset of the plurality of inter-metal dielectrics. The operations of 525 may be performed according to the methods and fabrication techniques described herein. In some examples, aspects of the operations of 525 may be performed using the fabrication techniques discussed with reference to FIGS. 2 through 4.

At 530, a PDN may be formed. In some examples, the PDN may be embedded at least partially within the first subset of the plurality of inter-metal dielectrics. The operations of 530 may be performed according to the methods and fabrication techniques described herein. In some examples, aspects of the operations of 530 may be performed using the fabrication techniques discussed with reference to FIGS. 2 through 4.

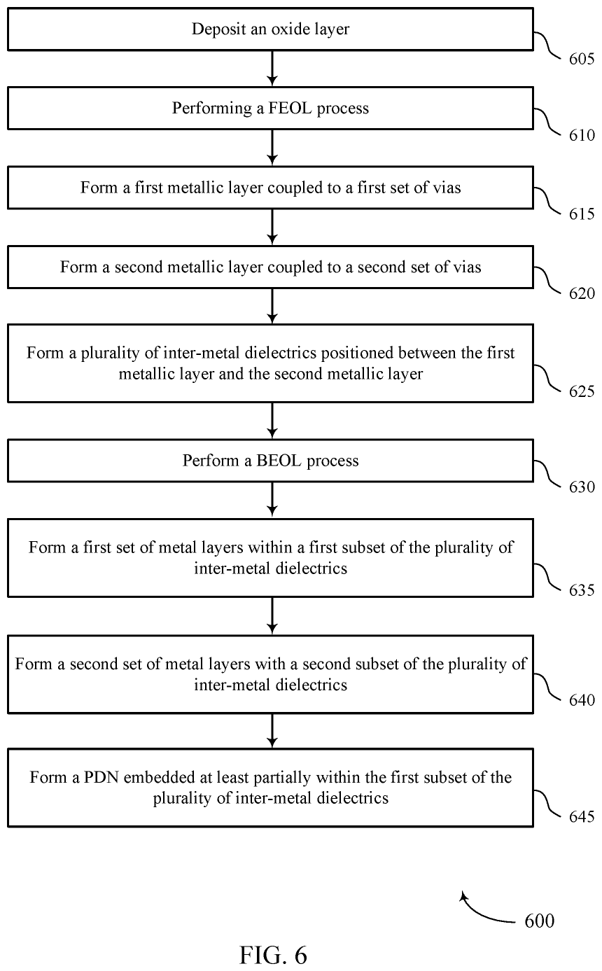

FIG. 6 shows a flowchart illustrating a method 600 for forming a semiconductor device in accordance with examples of the present disclosure. The operations of method 600 may be implemented by various fabrication techniques as described herein. For example, the operations of method 600 may be implemented by the fabrication techniques as discussed with reference to FIGS. 3 through 5.

At 605, an oxide layer may be deposited. In some examples, the oxide layer may be deposited on an upper surface of a wafer associated with the semiconductor device. The wafer may include a handle wafer or a glass wafer. The operations of 605 may be performed according to the methods and fabrication techniques described herein. In some examples, aspects of the operations of 605 may be performed using the fabrication techniques discussed with reference to FIGS. 2 through 4.

At 610, a FEOL process may be performed. The operations of 610 may be performed according to the methods and fabrication techniques described herein. In some examples, aspects of the operations of 610 may be performed using the fabrication techniques discussed with reference to FIGS. 2 through 4.

At 615, a first metallic layer may be formed. In some examples, the first metallic layer may be coupled to a first set of vias. The operations of 615 may be performed according to the methods and fabrication techniques described herein. In some examples, aspects of the operations of 615 may be performed using the fabrication techniques discussed with reference to FIGS. 2 through 4.

At 620, a second metallic layer may be formed. In some examples, the first metallic layer may be coupled to a second set of vias. The operations of 620 may be performed according to the methods and fabrication techniques described herein. In some examples, aspects of the operations of 620 may be performed using the fabrication techniques discussed with reference to FIGS. 2 through 4.

At 625, a plurality of inter-metal dielectrics may be formed and may be positioned between the first metallic layer and the second metallic layer. The operations of 625 may be performed according to the methods and fabrication techniques described herein. In some examples, aspects of the operations of 625 may be performed using the fabrication techniques discussed with reference to FIGS. 2 through 4.

At 630, a BEOL process may be performed. The operations of 630 may be performed according to the methods and fabrication techniques described herein. In some examples, aspects of the operations of 630 may be performed using the fabrication techniques discussed with reference to FIGS. 2 through 4.

At 635, a first set of metal layers may be formed. In some examples, the first set of metal layer may be formed within a first subset of the plurality of inter-metal dielectrics. The operations of 635 may be performed according to the methods and fabrication techniques described herein. In some examples, aspects of the operations of 635 may be performed using the fabrication techniques discussed with reference to FIGS. 2 through 4.

At 640, a second set of metal layers may be formed. In some examples, the second set of metal layer may be formed within a second subset of the plurality of inter-metal dielectrics different from the first subset of the plurality of inter-metal dielectrics. The operations of 640 may be performed according to the methods and fabrication techniques described herein. In some examples, aspects of the operations of 640 may be performed using the fabrication techniques discussed with reference to FIGS. 2 through 4.

At 645, a PDN may be formed. In some examples, the PDN may be embedded at least partially within the first subset of the plurality of inter-metal dielectrics. The operations of 645 may be performed according to the methods and fabrication techniques described herein. In some examples, aspects of the operations of 645 may be performed using the fabrication techniques discussed with reference to FIGS. 2 through 4.

It should be noted that the methods described herein describe possible implementations, and that the operations and the steps may be rearranged or otherwise modified and that other implementations are possible. Further, examples from two or more of the methods may be combined.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The term “electronic communication” and “coupled” refer to a relationship between components that support electron flow between the components. This may include a direct connection between components or may include intermediate components. Components in electronic communication or coupled to one another may be actively exchanging electrons or signals (e.g., in an energized circuit) or may not be actively exchanging electrons or signals (e.g., in a de-energized circuit) but may be configured and operable to exchange electrons or signals upon a circuit being energized. By way of example, two components physically connected via a switch (e.g., a transistor) are in electronic communication or may be coupled regardless of the state of the switch (i.e., open or closed).

The term “layer” used herein refers to a stratum or sheet of a geometrical structure. Each layer may have three dimensions (e.g., height, width, and depth) and may cover some or all of a surface. For example, a layer may be a three-dimensional structure where two dimensions are greater than a third, e.g., a thin-film. Layers may include different elements, components, and/or materials. In some cases, one layer may be composed of two or more sublayers. In some of the appended figures, two dimensions of a three-dimensional layer are depicted for purposes of illustration. Those skilled in the art will, however, recognize that the layers are three-dimensional in nature

As used herein, the term “substantially” means that the modified characteristic (e.g., a verb or adjective modified by the term substantially) need not be absolute but is close enough so as to achieve the advantages of the characteristic.

As used herein, the term “electrode” may refer to an electrical conductor, and in some cases, may be employed as an electrical contact to a memory cell or other component of a memory array. An electrode may include a trace, wire, conductive line, conductive layer, or the like that provides a conductive path between elements or components of a memory array.

The term “photolithography,” as used herein, may refer to the process of patterning using photoresist materials and exposing such materials using electromagnetic radiation. For example, a photoresist material may be formed on a base material by, for example, spin-coating the photoresist on the base material. A pattern may be created in the photoresist by exposing the photoresist to radiation. The pattern may be defined by, for example, a photo mask that spatially delineates where the radiation exposes the photoresist. Exposed photoresist areas may then be removed, for example, by chemical treatment, leaving behind the desired pattern. In some cases, the exposed regions may remain and the unexposed regions may be removed.

Chalcogenide materials may be materials or alloys that include at least one of the elements S, Se, and Te. Phase change materials discussed herein may be chalcogenide materials. Chalcogenide materials may include alloys of S, Se, Te, Ge, As, Al, Sb, Au, indium (In), gallium (Ga), tin (Sn), bismuth (Bi), palladium (Pd), cobalt (Co), oxygen (O), silver (Ag), nickel (Ni), platinum (Pt). Example chalcogenide materials and alloys may include, but are not limited to, Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, or Ge—Te—Sn—Pt. The hyphenated chemical composition notation, as used herein, indicates the elements included in a particular compound or alloy and is intended to represent all stoichiometries involving the indicated elements. For example, Ge—Te may include GeₓTe_{y}, where x and y may be any positive integer. Other examples of variable resistance materials may include binary metal oxide materials or mixed valence oxide including two or more metals, e.g., transition metals, alkaline earth metals, and/or rare earth metals. Embodiments are not limited to a particular variable resistance material or materials associated with the memory elements of the memory cells. For example, other examples of variable resistance materials can be used to form memory elements and may include chalcogenide materials, colossal magnetoresistive materials, or polymer-based materials, among others.

The term “isolated” refers to a relationship between components in which electrons are not presently capable of flowing between them; components are isolated from each other if there is an open circuit between them. For example, two components physically connected by a switch may be isolated from each other when the switch is open.

The devices discussed herein may be formed on a semiconductor substrate, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

1. A semiconductor device comprising:
a first metallic layer coupled to a first set of vias, each via of the first set coupled to a first contact and comprising a first plurality of metal layers;
a second metallic layer coupled to a second set of vias, each via of the second set coupled to a second contact and comprising a second plurality of metal layers;
a plurality of inter-metal dielectrics positioned between the first metallic layer and the second metallic layer;
a first set of metal layers within a first subset of the plurality of inter-metal dielectrics;
a second set of metal layers within a second subset of the plurality of inter-metal dielectrics, wherein the first subset and the second subset are different; and
a power delivery network embedded at least partially within the first subset of the plurality of inter-metal dielectrics.

2. The device of claim 1, further comprising:
a plurality of input and output contacts coupled to the second set of metal layers, wherein a portion of the plurality of input and output contacts are coupled to the second set of vias with a plurality of chips, and wherein the plurality of input and output contacts comprises the first contacts coupled with each via of the first set and comprises the second contacts coupled with each via of the second set.

3. The device of claim 2, further comprising:
a memory chip coupled to a first via through an input and output contact of the plurality of input and output contacts; and
a radio frequency chip coupled to a second via through a second input and output contact of the plurality of input and output contacts.

4. The device of claim 1, wherein the first set of metal layers and the second set of metal layers are coupled via a plurality of metal layers embedded within a third subset of the plurality of inter-metal dielectrics.

5. The device of claim 4, wherein the power delivery network is coupled to the first set of metal layers.

6. The device of claim 1, further comprising:
a set of n-type transistors coupled to the first set of metal layers or the second set of metal layers, or both; and
a set of p-type transistors coupled to the first set of metal layers or the second set of metal layers, or both, wherein the power delivery network is coupled to the set of n-type transistors or the set of p-type transistors, or both, via the first set of metal layers.

7. The device of claim 6, wherein the power delivery network further comprises:
a first voltage supply coupled to the set of n-type transistors; and
a second voltage supply coupled to the set of p-type transistors.

8. The device of claim 1, wherein vias of the first set of vias and the second set of vias are pseudo through-silicon vias.

9. The device of claim 1, wherein the first set of metal layers is formed based at last in part on a backside back end of a line metallization.

10. The device of claim 1, wherein the second set of metal layers is formed based at last in part on a frontside back end of a line metallization.

11. A method of forming a semiconductor device, comprising:
forming a first metallic layer coupled to a first set of vias
forming a second metallic layer coupled to a second set of vias;
forming a plurality of inter-metal dielectrics positioned between the first metallic layer and the second metallic layer;
forming a first set of metal layers within a first subset of the plurality of inter-metal dielectrics;
forming a second set of metal layers with a second subset of the plurality of inter-metal dielectrics, wherein the first subset and the second subset are different; and
forming a power delivery network embedded at least partially within the first subset of the plurality of inter-metal dielectrics.

12. The method of claim 11, further comprising:
depositing an oxide layer on an upper surface of a wafer associated with the semiconductor device, wherein the wafer comprises a handle wafer or a glass wafer.

13. The method of claim 12, further comprising:
depositing a graphene layer on an upper surface of the wafer; and
depositing one or more silicon layers on an upper surface of the graphene layer, wherein depositing the oxide layer comprises:
depositing the oxide layer on an upper surface of the silicon layer.

14. The method of claim 13, further comprising:
forming one or more silicon-germanium layers between the one or more silicon layers by interleaving the one or more silicon-germanium layers between the one or more silicon layers.

15. The method of claim 13, further comprising:
depositing a metal layer on an upper surface of the oxide layer, the metal layer comprising nickel.

16. The method of claim 13, further comprising:
positioning a thermal handle mechanism on an upper surface of the metal layer; and
performing a mechanical exfoliation of the graphene layer using the thermal handle mechanism.

17. The method of claim 16, further comprising:
forming a silicon on insulator wafer based at least in part on the mechanical exfoliation from the graphene layer using the thermal handle mechanism;
releasing the thermal handle mechanism based at least in part on forming the silicon on insulator wafer; and
performing an etching operation on the deposited metal layer on the upper surface of the oxide layer, wherein the etching operation comprises a wet etching operation.

18. The method of claim 11, wherein forming the semiconductor comprises:
performing a front end of a line patterning process.

19. The method of claim 11, wherein forming the semiconductor comprises:
performing a back end of a line patterning process based at least in part on performing the front end of a line patterning process.

20. A semiconductor device comprising:
a first pseudo through-silicon via coupled to a plurality of dielectric layers and comprising a first plurality of metal layers and a second plurality of metal layers;
a second pseudo through-silicon via coupled to the plurality of dielectric layers and comprising a third plurality of metal layers and a fourth plurality of metal layers;
a first set of metal layers coupled to a plurality of input and output contacts;
a second set of metal layers coupled to a power management integrated circuit;
a plurality of transistors coupled to the first set of metal layers; and
a plurality of voltage sources coupled to the second set of metal layers.
